(19) United States
(12) Patent Application Publication
(10) Pub. No.: US 2009/0189298 A1
(43) Pub. Date: Jul. 30, 2009

(54) Bonding pad structure and debug method thereof

(76) Inventors: Fu-Chung Wu, Taipei City (TW); Sheng-Yuan Tsai, Taipei City (TW)

Correspondence Address: Chih Feng Yeh;BRIAN M. MCINNIS, 12th Floor, Ruttonjee House, 11 Duddell Street, Hong Kong, HK

(21) Appl. No.: 12/010,571

(22) Filed: Jan. 28, 2008

(51) Int. Cl. H01L 23/48; H01L 21/44

(52) U.S. Cl. 257/782; 438/612; 257/E23.02

(57) ABSTRACT

The bonding pad structure includes a main bonding pad and a blank path. The blank path crosses through the main bonding pad for dividing the main bonding pad into a first sub-bonding pad and a second sub-bonding pad. The bonding pad structure may further include a solder covered on the blank path and the main bonding pad selectively. The main bonding pad is regarded as a closed circuit when the solder is covered on the blank path and the main bonding pad. The main bonding pad is regarded as a open circuit when the solder is not covered on the blank path and the main bonding pad. A debug method with the bonding pad structure is also disclosed.

### BACKGROUND

1. Field of Invention

The present invention relates to a bonding pad structure. More particularly, the present invention relates to a bonding pad structure for debug process.

2. Description of Related Art

A debug process is usually applied after the IC devices mounted on the printed circuit board to ensure the printed circuit board and the IC chips operate normally. The debug process is usually applied after the layout process. The components for the debug process are built on the printed circuit board at the layout process. There is a 0 ohm resistor arranged on the debug position of the printed circuit board to prevent short circuits and maintain the rework flexibility at the debug process. The 0 ohm resistor can be removed during the debug process, and the debug engineer can debug the components leading to the debug position respectively. The material and the cost for building the 0 ohm resistor need to be considered.

### SUMMARY

The invention provides a bonding pad structure for a debug process of a printed circuit board. The bonding pad structure includes a main bonding pad and a blank path. The blank path crosses through the main bonding pad for dividing the main bonding pad into a first sub-bonding pad and a second sub-bonding pad. The bonding pad structure may further include a solder covered on the blank path and the main bonding pad selectively. The main bonding pad is regarded as a close circuit when the solder is covered on the blank path and the main bonding pad. The main bonding pad is regarded as a close circuit when the solder is not covered on the blank path and the main bonding pad.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is an embodiment of a bonding pad structure of the invention;

FIG. 2A and FIG. 2B are schematic diagrams of different embodiments of the bonding pad structure of the invention;

FIG. 3 is another embodiment of the bonding pad structure of the invention; and

FIG. 4 is a flow chart diagram of the embodiment of a debug method with the bonding pad structure of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

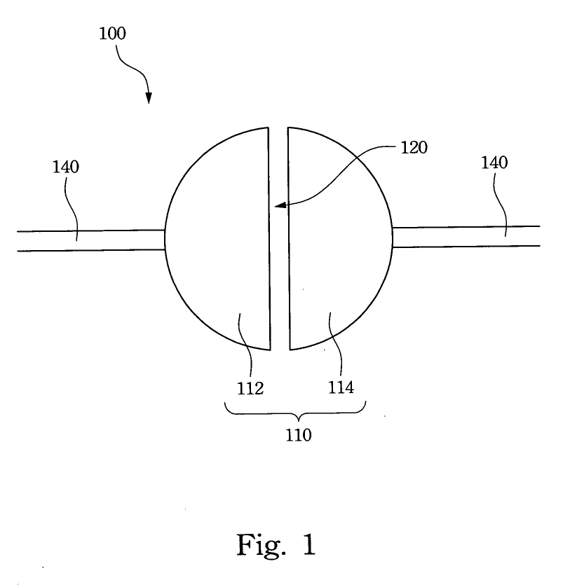

Refer to FIG. 1. FIG. 1 illustrates an embodiment of a bonding pad structure of the invention. The bonding pad structure 100 includes a main bonding pad 110 and a blank path 120. The blank path 120 may cross through the main bonding pad 110 and divide the main bonding pad 110 into a first sub-bonding pad 112 and a second sub-bonding pad 114. The blank path 120 is arranged between the first sub-bonding pad 114 and the second sub-bonding pad 114.

The blank path 12 separate the first sub-bonding pad 112 and the second sub-bonding pad 114. The first sub-bonding pad 112 does not connect with the second sub-bonding pad 114. The main bonding pad 110 may be regarded as an open circuit. The first sub-bonding pad 112 and the second sub-bonding pad 114 may be regarded as a debug point respectively at the debug process. The first sub-bonding pad 112 and the second sub-bonding pad 114 may be a part of the main bonding pad 110. For example, the shape of the main bonding pad may be a circle, and the blank path may be a straight line. The first sub-bonding pad 112 and the second sub-bonding pad 114 may both be semicircles respectively. The first sub-bonding pad 112 and the second sub-bonding pad 114 may lead to an external point. The first sub-bonding pad 112 and the second sub-bonding pad 1 14 may lead to an IC chip pin or a via respectively.

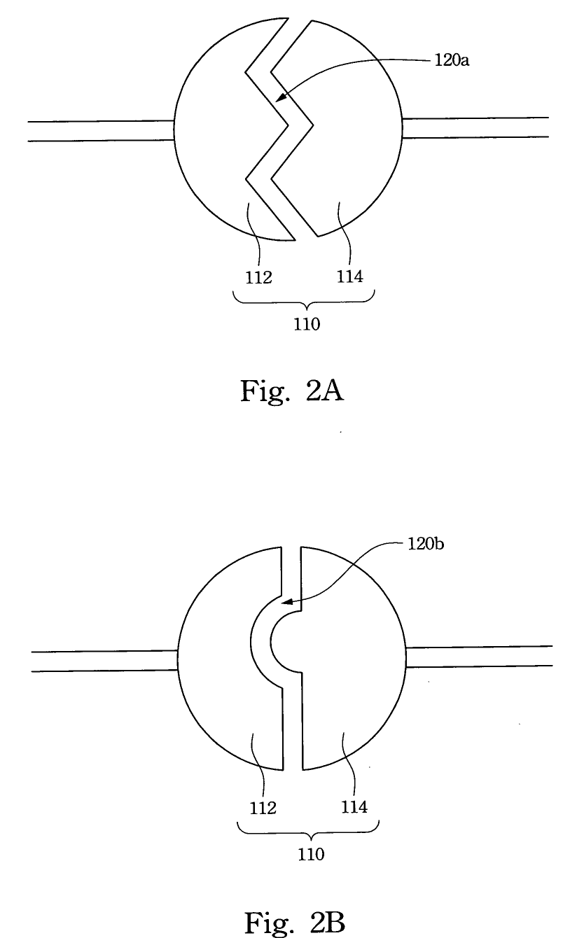

Refer to FIG. 2A and FIG. 2B. FIG. 2A and FIG. 2B illustrate schematic diagrams of different embodiments of the bonding pad structure of the invention. The shape of the blank path 120a may be a curved line as shown in FIG. 2A. The shape of the blank path 120b may be a broken line as shown in FIG. 2B. The shape of the blank path 120 is not limited with the above embodiments. The blank path 120 is designed to cross through the main bonding pad 110 and dividing the main bonding pad 110 into the first sub-bonding pad 112 and the second sub-bonding pad 114.

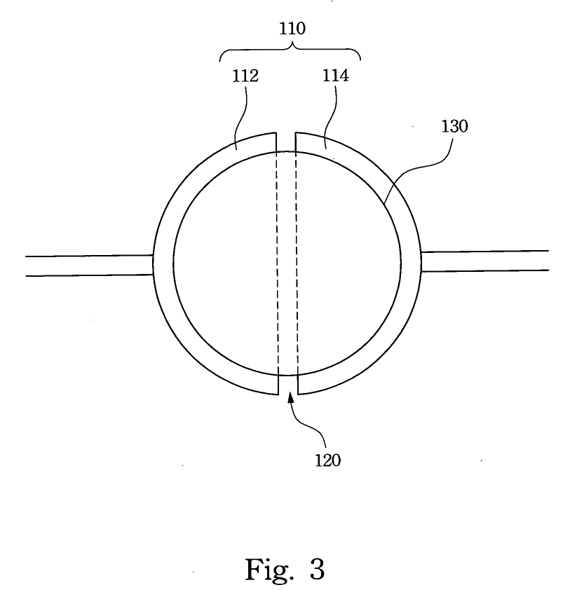

Refer to FIG. 3. FIG. 3 illustrates another embodiment of the bonding pad structure of the invention. The bonding pad structure 100 may further include a solder 130. The solder 130 may be covered on the blank path 120 and the main bonding pad 110 selectively to connect the first sub-bonding pad 112 and the second sub-bonding pad 114. The main bonding pad 110 covered with the solder 130 may be regarded as a closed circuit. The solder 130 may be a tin paste. The amount of the solder 130 needs to connect the first sub-bonding pad 112 and the second sub-bonding pad 114. The solder 130 may be covered on the main bonding pad completely.

The bonding pad structure 100 of the embodiments may also prevent the circuit board layout from plagiarizing. The bonding pad structure 100 of the invention may be regarded as the open circuit if a third party got the circuit board with the bonding pad structure 100 from an unsuitable method but cannot understand the spirit of the blank path 120 of the invention. However, the blank path 120 of the invention can be covered with the solder 130 and become the close circuit. The third party cannot understand the spirit of the blank path 120 and cannot get the correct and complete circuit board layout.

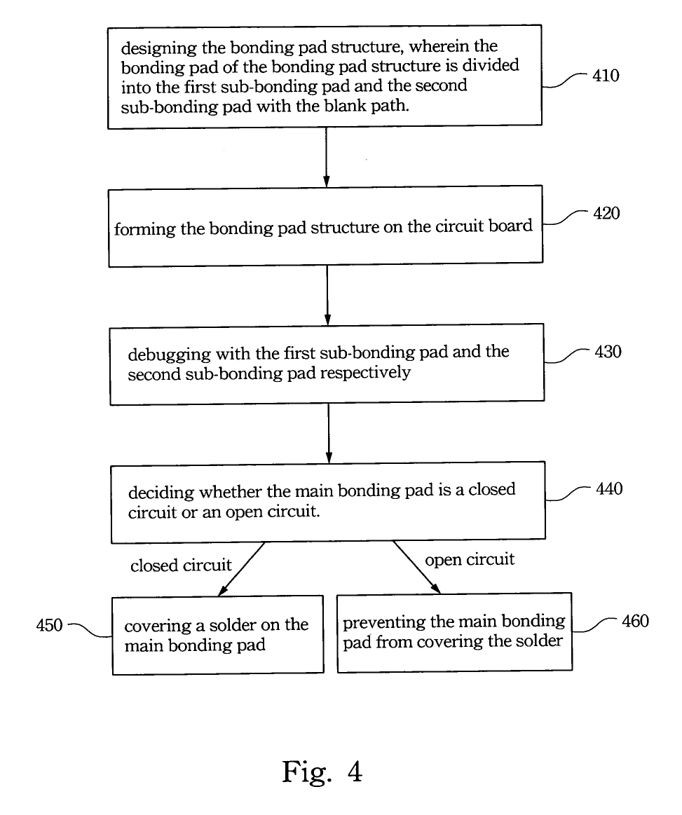

Refer to FIG. 4. FIG. 4 illustrates a flow chart diagram of the embodiment of a debug method with the bonding pad structure of the invention. The debug method starts at step 410, which is designing the bonding pad structure. Step 410 includes providing a symbol corresponding to the bonding pad structure for designing the circuit layout. The main bonding pad of the bonding pad structure is divided into the first sub-bonding pad and the second sub-bonding pad with the blank path. Then, in step 420 the bonding pad structure is formed on the circuit board. In Step 430 debugging is done with the first sub-bonding pad and the second sub-bonding pad respectively. In Step 440 a decision is made about whether the main bonding pad is a closed circuit or an open circuit after the debug process. If the main bonding pad is a closed circuit, in step 450 the solder is covered on the main bonding pad to connect the first sub-bonding pad and the second sub-bonding pad. Step 450 may be executed with a solder paste printing process. If the main bonding pad is an open circuit, in Step 460 the main bonding pad is prevented from covering the solder.

The bonding pad structure may be formed on the circuit board with other normal bonding pads and replace the conventional 0 ohm resistor at the debug process. The material and the process for preparing the 0 ohm resistor can be omitted. The solder may be covered on the blank path and the main bonding pad selectively. The main bonding pad may be regarded as a closed circuit when the solder is covered on the blank path and the main bonding pad. The main bonding pad may be regarded as a open circuit when the solder is not covered on the blank path and the main bonding pad.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bonding pad structure for a debug process of a printed circuit board, the bonding pad structure comprising:
a main bonding pad;
a blank path crossing through the main bonding pad to divide the main bonding pad into a first sub-bonding pad and a second sub-bonding pad; and
a solder covered on the blank path and the main bonding pad selectively, wherein the main bonding pad is a closed circuit when the solder is covered on the blank path and the main bonding pad; the main bonding pad is a open circuit when the solder is not covered on the blank path and the main bonding pad.

2. The bonding pad structure of claim 1, wherein a shape of the main bonding pad is a circle.

3. The bonding pad structure of claim 1, wherein the first sub-bonding pad and the second sub-bonding pad are leading to a via or a IC chip pin respectively.

4. The bonding pad structure of claim 1, wherein a shape of the blank path is a straight line.

5. The bonding pad structure of claim 1, wherein a shape of the blank path is a broken line.

6. The bonding pad structure of claim 1, wherein a shape of the blank path is a curved line.

7. The bonding pad structure of claim 1, wherein solder is covered on the main bonding pad completely.

8. A bonding pad structure for a debug process of a printed circuit board, the bonding pad structure comprising:
a main bonding pad; and
a blank path crossing through the main bonding pad for dividing the main bonding pad into a first sub-bonding pad and a second sub-bonding pad.

9. The bonding pad structure of claim 8, wherein a shape of the main bonding pad is a circle.

10. The bonding pad structure of claim 8, wherein the first sub-bonding pad and the second sub-bonding pad lead to a via or an IC chip pin respectively.

11. The bonding pad structure of claim 8, wherein the shape of the blank path is a straight line.

12. The bonding pad structure of claim 8, wherein a shape of the blank path is a broken line.

13. The bonding pad structure of claim 8, wherein a shape of the blank path is a curved line.

14. A debug method with a bonding pad structure comprising:
designing the bonding pad structure, wherein the bonding pad structure comprises a main bonding pad, which is divided into a first sub-bonding pad and a second sub-bonding pad with a blank path;
forming the bonding pad structure a circuit board;
debugging with the first sub-bonding pad and the second sub-bonding pad respectively; and
deciding whether the main bonding pad is a closed circuit or an open circuit.

15. The debug method with the bonding pad structure of claim 14, further comprising covering a solder on the main bonding pad to connect the first sub-bonding pad and the second sub-bonding pad when the main bonding pad is a closed circuit.
